(19) United States
(12) Patent Application Publication
(10) Pub. No.: US 2022/0399874 A1
(43) Pub. Date: Dec. 15, 2022

(54) ACOUSTIC WAVE RESONATOR PACKAGE

(71) Applicant: SAMSUNG ELECTRO-MECHANICS CO., LTD., Suwon-si (KR)

(72) Inventors: Tae Kyung LEE, Suwon-si (KR); Sang Heon HAN, Suwon-si (KR); Hwa Sun LEE, Suwon-si (KR); Jae Goon AUM, Suwon-si (KR); Sung HAN, Suwon-si (KR)

(73) Assignee: SAMSUNG ELECTRO-MECHANICS CO., LTD., Suwon-si (KR)

(21) Appl. No.: 17/511,696

(22) Filed: Oct. 27, 2021

(30) Foreign Application Priority Data
Jun. 10, 2021 (KR) 10-2021-0075581

(51) Int. Cl. H03H 9/17; H03H 9/13; H03H 9/02; H03H 3/02

(52) U.S. Cl. CPC H03H 9/17; H03H 9/131; H03H 9/02015; H03H 3/02

(57) ABSTRACT

An acoustic wave resonator package is provided. The acoustic wave resonator package includes an acoustic wave resonator including an acoustic wave generator on a first surface of a substrate; a cover disposed to face the first surface of the substrate; a bonding member disposed between the substrate and the cover, and configured to bond a bonding surface of the acoustic wave generator and the cover to each other, wherein the bonding member includes glass frit, and the bonding surface of the acoustic wave resonator which is bonded to the bonding member may be formed of a dielectric material.

### CROSS-REFERENCE TO RELATED APPLICATIONS

This application claims the benefit under 35 USC § 119(a) of Korean Patent Application No. 10-2021-0075581 filed on Jun. 10, 2021 in the Korean Intellectual Property Office, the entire disclosure of which is incorporated herein by references for all purposes.

### BACKGROUND

### 1. Field

The following description relates to an acoustic wave resonator package.

### 2. Description of Related Art

Recently, wireless communication devices have been developed with a miniaturized form factor. For example, a bulk-acoustic wave (BAW) resonator-type filter that is implemented with semiconductor thin film wafer manufacturing technology, may be used.

A BAW is formed when a thin film type element causes resonance using a piezoelectric dielectric material on a silicon wafer, a semiconductor substrate, based on the piezoelectric characteristics thereof. The BAW may be implemented as a filter.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, an acoustic wave resonator package includes an acoustic wave resonator, comprising an acoustic wave generator disposed on a first surface of a substrate; a cover, disposed to face the first surface of the substrate; a bonding member, disposed between the substrate and the cover, and configured to bond a bonding surface of the acoustic wave resonator and the cover to each other, wherein the bonding member comprises glass frit, and wherein the bonding surface of the acoustic wave resonator is formed of a dielectric material.

The cover may be formed of a glass material.

The bonding member may be disposed along an edge of the cover, and is disposed to continuously surround the acoustic wave generator.

The bonding member may include any one of V₂O₃, TaO₂, B₂O₃, ZnO, B₂O₃, and Bi₂O₃.

The bonding surface of the acoustic wave resonator may be formed of any one of SiO₂, Si₃N₄, TiO₂, Al₂O₃, AlN, ZrO₂, amorphous silicon, and poly-silicon.

The acoustic wave generator comprises a resonator having a first electrode, a piezoelectric layer, and a second electrode sequentially stacked on the substrate.

The acoustic wave resonator may further include a protective layer, disposed along a surface of the acoustic wave generator, and

The bonding member may be bonded to the protective layer.

The protective layer may be formed of any one of SiO₂, Si₃N₄, TiO₂, Al₂O₃, AlN, ZrO₂, amorphous silicon (a-Si), and poly-silicon (Poly Si).

The acoustic wave resonator may further include a support layer, disposed between the resonator and the substrate, and configured to separate the resonator and the substrate by a predetermined distance, and wherein the bonding member is bonded to the support layer.

The support layer may be formed of a poly-silicon (Poly Si) material.

The acoustic wave resonator package may further include a support portion, disposed on the acoustic wave resonator, and may be configured to face the bonding member, wherein an upper surface of the support portion may be configured to form a bonding surface of the acoustic wave resonator.

An upper end of the support portion may be disposed to be closer to the cover than an upper end of the acoustic wave generator.

The cover may be configured to have a groove in a region that faces the acoustic wave generator.

The acoustic wave resonator may further include a hydrophobic layer disposed along a surface of the acoustic wave generator.

The acoustic wave resonator package may further include a connection terminal, disposed on a second surface of the substrate; and a connection conductor, disposed to pass through the substrate and electrically connect the acoustic wave generator to the connection terminal.

In a general aspect, an acoustic wave resonator package includes an acoustic wave resonator, comprising an acoustic wave generator disposed on a first surface of a substrate; a cover, formed of a glass material, and disposed to face the first surface of the substrate; and a bonding member, disposed between the substrate and the cover, and configured to bond the acoustic wave resonator and the cover to each other, wherein the bonding member comprises glass frit, and wherein the cover is configured to have a groove in a region that faces the acoustic wave generator.

In a general aspect, an acoustic wave resonator package includes a resonator, disposed on a first surface of a substrate; a cover, disposed over the resonator; an insulating layer, provided on an upper surface of the substrate; and a bonding member, configured to bond the cover to the insulating layer; wherein the cover is formed of a glass material, and wherein the bonding material comprises glass frit.

The bonding member may be formed of one of V₂O₃, TaO₂, B₂O₃, ZnO, B₂O₃, and Bi₂O₃.

Other features and aspects will be apparent from the following detailed description, the drawings, and the claims.

### BRIEF DESCRIPTION OF DRAWINGS

FIG. 1 is a plan view of an example acoustic wave resonator, in accordance with one or more embodiments.

FIG. 2 is an example cross-sectional view taken along line I-I′ of FIG. 1.

FIG. 3 is an example cross-sectional view taken along line II-II′ of FIG. 1.

FIG. 4 is an example cross-sectional view taken along line III-III′ of FIG. 1.

FIG. 5 is an example cross-sectional view schematically illustrating an example acoustic wave resonator package, in accordance with one or more embodiments.

FIGS. 6A and 6B are views illustrating an example method of manufacturing the example acoustic wave resonator package illustrated in FIG. 5.

FIG. 7 is an example bottom perspective view of the cover and the bonding member illustrated in FIG. 5.

FIG. 8 is an example cross-sectional view schematically illustrating an example acoustic wave resonator package, in accordance with one or more embodiments.

FIG. 9 is an example cross-sectional view schematically illustrating an example acoustic wave resonator package, in accordance with one or more embodiments.

FIG. 10 an example cross-sectional view schematically illustrating an example acoustic wave resonator package, in accordance with one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of the application, may be omitted for increased clarity and conciseness.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains after an understanding of the disclosure of this application. Terms, such as those defined in commonly used dictionaries, are to be interpreted as having a meaning that is consistent with their meaning in the context of the relevant art and the disclosure of the present application, and are not to be interpreted in an idealized or overly formal sense unless expressly so defined herein.

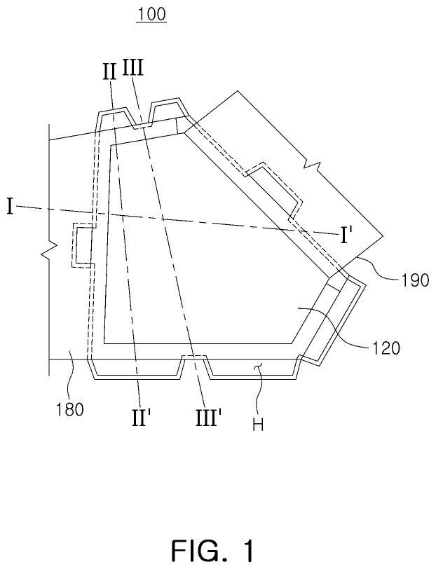

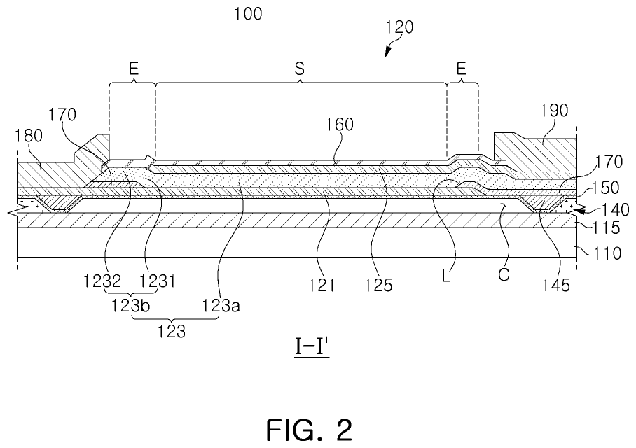

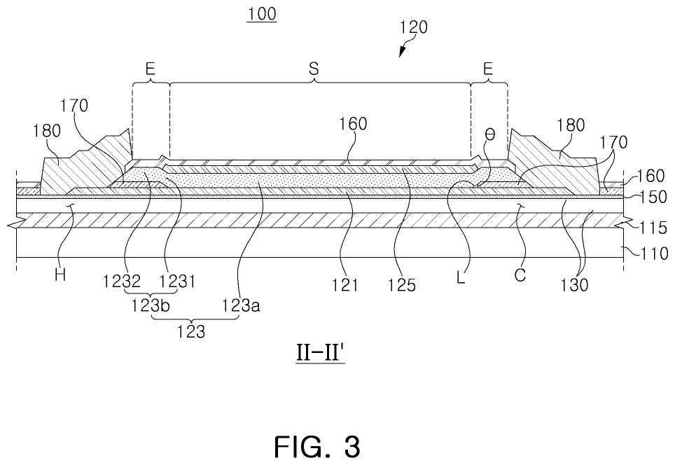

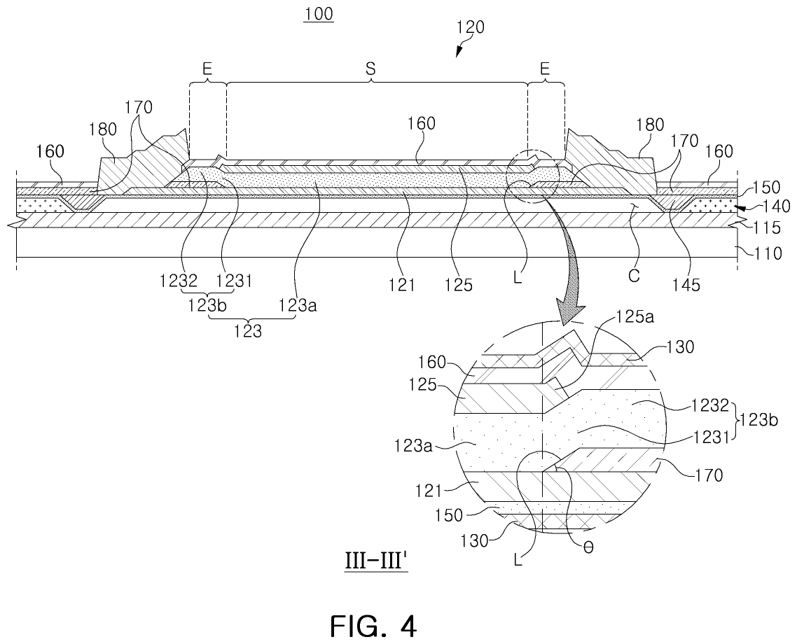

FIG. 1 is a plan view of an example acoustic wave resonator, in accordance with one or more embodiments, FIG. 2 is an example cross-sectional view taken along line I-I′ of FIG. 1, FIG. 3 is an example cross-sectional view taken along line II-II′ of FIG. 1, and FIG. 4 is an example cross-sectional view taken along line III-III′ of FIG. 1.

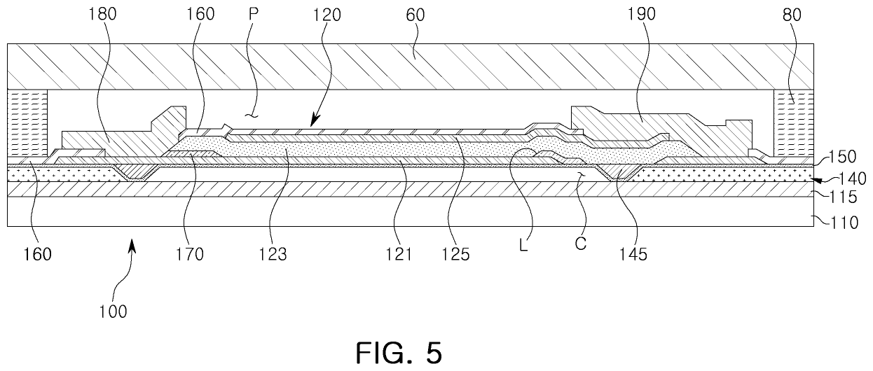

Referring to FIGS. 1 to 4, an example acoustic wave resonator 100, in accordance with one or more embodiments, may be, as a non-limiting example, a bulk-acoustic wave (BAW) resonator, and may include a substrate 110, an insulating layer 115, a resonator 120, and a cover 60 (FIG. 5). Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

The substrate 110 may be a silicon substrate. In one or more examples, a silicon wafer or a silicon-on-insulator (SOI)-type substrate may be used as the substrate 110.

An insulating layer 115 may be provided on an upper surface of the substrate 110, to electrically isolate the substrate 110 from the resonator 120. Additionally, the insulating layer 115 may help prevent the substrate 110 from being etched by an etching gas, when a cavity C is formed in a manufacturing process of the acoustic wave resonator.

In one or more examples, the insulating layer 115 may be formed of at least one among silicon dioxide (SiO₂), silicon nitride (Si₃N₄), aluminum oxide (Al₂O₃), and aluminum nitride (AlN), and may be formed through a process, such as, but not limited to, chemical vapor deposition (CVD), RF magnetron sputtering, and evaporation.

A support layer 140 may be formed on the insulating layer 115, and may be disposed around a cavity C. An etch stop portion 145 may surround the cavity C, and may be disposed inside the support layer 140.

The cavity C may be formed as a void, and may be formed by removing a portion of the sacrificial layer 140. The support layer 140 may be formed as a remaining portion of the sacrificial layer.

The support layer 140 may be formed of a material such as, but not limited to, polysilicon or a polymer that is relatively easy to etch. However, the support layer 140 is not limited thereto.

The etch stop portion 145 may be disposed along a boundary of the cavity C. The etch stop portion 145 may be provided to prevent etching from being performed beyond a cavity region during a process of forming the cavity C.

A membrane layer 150 may be formed on the support layer 140, and may form an upper surface of the cavity C. Therefore, the membrane layer 150 may also be formed of a material that is not easily removed in the process of forming the cavity C.

In one or more examples, when a halide-based etching gas such as fluorine (F), chlorine (Cl), or the like is used to remove a portion (e.g., a cavity region) of the support layer 140, the membrane layer 150 may be formed of a material having low reactivity with the etching gas. In such an example, the membrane layer 150 may include at least one of silicon dioxide (SiO₂) and silicon nitride (Si₃N₄).

Additionally, the membrane layer 150 may be formed of a dielectric layer containing at least one material of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or a metal layer containing at least one material of aluminum (Al), nickel (Ni), chromium (Cr), platinum (Pt), gallium (Ga), and hafnium (Hf). However, a configuration of the one or more examples is not limited thereto.

The resonator 120 includes a first electrode 121, a piezoelectric layer 123, and a second electrode 125. The resonator 120 is configured such that the first electrode 121, the piezoelectric layer 123, and the second electrode 125 are stacked in order from a bottom to a top of the example acoustic wave resonator 100. Therefore, the piezoelectric layer 123 in the resonator 120 may be disposed between the first electrode 121 and the second electrode 125.

Since the resonator 120 may be formed on the membrane layer 150, the membrane layer 150, the first electrode 121, the piezoelectric layer 123, and the second electrode 125 are sequentially stacked on the substrate 110, to form the resonator 120.

The resonator 120 may resonate the piezoelectric layer 123 according to signals applied to the first electrode 121 and the second electrode 125 to generate a resonant frequency and an anti-resonant frequency.

The resonator 120 may be divided into a central portion S in which the first electrode 121, the piezoelectric layer 123, and the second electrode 125 are stacked to be substantially flat, and an extension portion E in which an insertion layer 170 is interposed between the first electrode 121 and the piezoelectric layer 123.

The central portion S of the example acoustic wave resonator 100 is a region disposed in a center of the resonator 120, and the extension portion E is a region disposed along a periphery of the central portion S. Therefore, the extension portion E is a region extended from the central portion S externally, and may mean a region formed to have a continuous annular shape along the periphery of the central portion S. However, if necessary, the extension portion E may be configured to have a discontinuous annular shape, in which some regions are disconnected.

Accordingly, as illustrated in FIG. 2, in the cross-section of the resonator 120 cut so as to cross the central portion S, the extension portion E may be disposed on both ends of the central portion S, respectively. An insertion layer 170 may be disposed on both sides of the extension portion E disposed on both ends of the central portion S.

The insertion layer 170 may have an inclined surface L of which a thickness becomes greater as a distance from the central portion S increases.

In the extension portion E, the piezoelectric layer 123 and the second electrode 125 may be disposed on the insertion layer 170. Therefore, the piezoelectric layer 123 and the second electrode 125 located in the extension portion E may have an inclined surface along the shape of the insertion layer 170.

In one or more examples, the extension portion E may be included in the resonator 120, and accordingly, resonance may also occur in the extension portion E. However, the one or more examples are not limited thereto, and resonance may not occur in the extension portion E depending on the structure of the extension portion E, and resonance may only occur in the central portion S.

The first electrode 121 and the second electrode 125 may be formed of a conductor, such as, but not limited to, gold, molybdenum, ruthenium, iridium, aluminum, platinum, titanium, tungsten, palladium, tantalum, chromium, nickel, or a metal containing at least one thereof, but is not limited thereto.

In the resonator 120, the first electrode 121 may be formed to have a larger surface area than the second electrode 125, and a first metal layer 180 may be disposed along a periphery of the first electrode 121 on the first electrode 121. Therefore, the first metal layer 180 may be disposed to be spaced apart from the second electrode 125 by a predetermined distance, and may be disposed in a form surrounding the resonator 120.

Since the first electrode 121 may be disposed on the membrane layer 150, the first electrode 121 may be formed to be entirely flat. On the other hand, since the second electrode 125 is disposed on the piezoelectric layer 123, the second electrode 125 may be formed to be curved in a manner that corresponds to the shape of the piezoelectric layer 123.

The first electrode 121 may be used as any one of an input electrode and an output electrode that inputs and outputs an electrical signal such as a radio frequency (RF) signal, or the like.

In a non-limiting example, the second electrode 125 may be entirely disposed in the central portion S, and may be partially disposed in the extension portion E. Accordingly, the second electrode 125 may be divided into a portion 123a disposed on a piezoelectric portion of the piezoelectric layer 123 to be described later, and a portion 123b disposed on a curved portion of the piezoelectric layer 123.

In one or more examples, the second electrode 125 may be disposed to cover an entirety of the piezoelectric portion 123a and a portion of an inclined portion 1231 of the piezoelectric layer 123. Accordingly, the second electrode (125a in FIG. 4) disposed in the extension portion E may be formed to have a smaller area than an inclined surface of the inclined portion 1231, and the second electrode 125 in the resonator 120 is formed to have a smaller area than the piezoelectric layer 123.

Accordingly, as illustrated in FIG. 2, in a cross-section of the resonator 120 cut so as to cross the central portion S, an end of the second electrode 125 may be disposed in the extension portion E. Additionally, the end of the second electrode 125 disposed in the extension portion E may be disposed such that at least a portion thereof overlaps the insertion layer 170. Here, ‘overlap’ means that if the second electrode 125 is projected onto a plane on which the insertion layer 170 is disposed, a shape of the second electrode 125 projected on the plane would overlap, or be disposed over, the insertion layer 170.

The second electrode 125 may be used as any one of an input electrode and an output electrode to input and output an electrical signal such as a radio frequency (RF) signal, or the like. That is, when the first electrode 121 is implemented as the input electrode, the second electrode 125 may be implemented as the output electrode, and when the first electrode 121 is implemented as the output electrode, the second electrode 125 may be implemented as the input electrode.

In one or more examples, as illustrated in FIG. 4, when an end of the second electrode 125 is positioned on the inclined portion 1231 of the piezoelectric layer 123 to be described later, since a local structure of an acoustic impedance of the resonator 120 may be formed in a sparse/dense/sparse/dense structure from the central portion S, a reflective interface reflecting a lateral wave inwardly of the resonator 120 increases. Therefore, since most lateral waves may not flow outwardly of the resonator 120, and may be reflected and then flow to an interior of the resonator 120, the performance of the acoustic wave resonator may be improved.

The piezoelectric layer 123 is a portion of the example acoustic wave resonator 100 in which a piezoelectric effect that converts electrical energy into mechanical energy in a form of elastic waves occurs. The piezoelectric layer 123 may be formed on the first electrode 121 and the insertion layer 170, as will be described later.

As a material of the piezoelectric layer 123, zinc oxide (ZnO), aluminum nitride (AlN), doped aluminum nitride, lead zirconate titanate, quartz, and the like may be selectively used. In an example of doped aluminum nitride, a rare earth metal, a transition metal, or an alkaline earth metal may be further included. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

The piezoelectric layer 123, in accordance with one or more embodiments, may include a piezoelectric portion 123a disposed in a central portion S of the example acoustic wave resonator 100, and a curved portion 123b disposed in an extension portion E of the example acoustic wave resonator 100.

The piezoelectric portion 123a is a portion that may be directly stacked on the upper surface of the first electrode 121. Therefore, the piezoelectric portion 123a may be interposed between the first electrode 121 and the second electrode 125, and may be formed as a flat shape, together with the first electrode 121 and the second electrode 125.

The curved portion 123b of the piezoelectric layer 123 may be defined as a region that extends externally from the piezoelectric portion 123a of the piezoelectric layer 123, and may be positioned in the extension portion E.

The curved portion 123b may be disposed on the insertion layer 170, as is described later, and may be formed in a shape in which the upper surface thereof is raised along the shape of the insertion layer 170. Accordingly, the piezoelectric layer 123 may be curved at a boundary between the piezoelectric portion 123a and the curved portion 123b, and the curved portion 123b may be raised, corresponding to the thickness and shape of the insertion layer 170.

The curved portion 123b may be divided into an inclined portion 1231 and an extension portion 1232.

The inclined portion 1231 means a portion of the piezoelectric layer 123 that may be formed to be inclined along an inclined surface L of the insertion layer 170, as is described later. The extension portion 1232 means a portion of the piezoelectric layer 123 that extends externally from the inclined portion 1231 of the piezoelectric layer 123.

The inclined portion 1231 may be formed to be parallel to the inclined surface L of the insertion layer 170, and an inclination angle of the inclined portion 1231 may be formed to be the same as an inclination angle of the inclined surface L of the insertion layer 170.

The insertion layer 170 may be disposed along a surface that is formed by the membrane layer 150, the first electrode 121, and the etch stop portion 145. Therefore, the insertion layer 170 may be partially disposed in the resonator 120, and may be disposed between the first electrode 121 and the piezoelectric layer 123.

The insertion layer 170 may be disposed around the central portion S to support the curved portion 123b of the piezoelectric layer 123. Accordingly, the curved portion 123b of the piezoelectric layer 123 may be divided into an inclined portion 1231, and an extension portion 1232, according to the shape of the insertion layer 170.

In one or more examples, the insertion layer 170 may be disposed in a region except for, or external to, the central portion S. In a non-limiting example, the insertion layer 170 may be disposed in an entire region except for, or external to, the central portion S, or only in some regions (for example, in the extension portion) on the substrate 110.

The insertion layer 170 may be formed to have a thickness that increases as a distance from the central portion S increases. Accordingly, the insertion layer 170 may be formed to have an inclined surface L which has a constant inclination angle θ of the side surface disposed adjacent to the central portion S.

When the inclination angle θ of the side surface of the insertion layer 170 is formed to be smaller than 5°, in order to manufacture the same, since the thickness of the insertion layer 170 should be formed to be very thin, or an area of the inclined surface L should be formed to be excessively large, it may be difficult to be implemented.

Additionally, when the inclination angle θ of the side surface of the insertion layer 170 is formed to be greater than 70°, the inclination angle of the piezoelectric layer 123 or the second electrode 125 stacked on the insertion layer 170 may also be formed to be greater than 70°. In such an example, since the piezoelectric layer 123 or the second electrode 125 stacked on the inclined surface L is excessively curved, cracks may be generated in the curved portion.

Therefore, in one or more examples, the inclination angle θ of the inclined surface L may be formed in a range of 5° or more and 70° or less.

Further, in one or more examples, the inclined portion 1231 of the piezoelectric layer 123 may be formed along the inclined surface L of the insertion layer 170. Accordingly, the inclination angle of the inclination portion 1231 may be formed in the range of 5° or more, and 70° or less, similarly to the inclined surface L of the insertion layer 170. The configuration may also be equally applied to the second electrode 125 stacked on the inclined surface L of the insertion layer 170.

The insertion layer 170 may be formed of a dielectric such as, but not limited to, silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), or the like, and may be formed a material different from that of the piezoelectric layer 123.

Additionally, the insertion layer 170 may be implemented with a metal material. When an acoustic wave resonator of one or more examples is used for 5G communications, heat generated from the resonator 120 may be smoothly discharged because a high level of heat may be generated from the resonator. Accordingly, the insertion layer 170 of the one or more examples may be formed of an aluminum alloy material containing scandium (Sc).

The resonator 120 may be disposed to be spaced apart from the substrate 110 through a cavity C formed as a void.

The cavity C may be formed by removing a portion of the support layer 140 by supplying an etching gas (or an etching solution) to an inlet hole (H in FIG. 1) during a manufacturing process of the acoustic wave resonator.

Accordingly, the cavity C may be composed of a space in which an upper surface (a ceiling surface) and a side surface (a wall surface) are formed by the membrane layer 150, and a bottom surface is formed by the substrate 110 or the insulating layer 115.

In a non-limiting example, the membrane layer 150 may be formed only on the upper surface (the ceiling surface) of the cavity C.

In an example, a protective layer 160 may be disposed along a surface of the acoustic wave resonator 100 to protect the acoustic wave resonator 100 from external environmental factors. The protective layer 160 may be disposed along a surface formed by the second electrode 125 and the curved portion 123b of the piezoelectric layer 123.

In an example, the protective layer 160 may be partially removed for frequency control in a final process during the manufacturing process. In an example, the thickness of the protective layer 1160 may be controlled through frequency trimming during the manufacturing process.

Accordingly, the protective layer 160 may include one of silicon oxide (SiO₂), silicon nitride (Si₃N₄), magnesium oxide (MgO), zirconium oxide (ZrO₂), aluminum nitride (AlN), lead zirconate titanate (PZT), gallium Arsenic (GaAs), hafnium oxide (HfO₂), aluminum oxide (Al₂O₃), titanium oxide (TiO₂), zinc oxide (ZnO), amorphous silicon (a-Si), and polycrystalline silicon (p-Si), suitable for frequency trimming. However, the examples are not limited thereto, and various modifications are possible, such as forming the protective layer 160 with a diamond thin film in order to increase a heat dissipation effect.

The first electrode 121 and the second electrode 125 may extend in a direction external to the resonator 120. A first metal layer 180 and a second metal layer 190 may be disposed on an upper surface of the extended portion, respectively.

The first metal layer 180 and the second metal layer 190 may be formed of any one material of gold (Au), a gold-tin (Au—Sn) alloy, copper (Cu), a copper-tin (Cu—Sn) alloy, and aluminum (Al), and an aluminum alloy. Here, the aluminum alloy may be an aluminum-germanium (Al—Ge) alloy or an aluminum-scandium (Al—Sc) alloy.

The first metal layer 180 and the second metal layer 190 may be implemented as a connection that electrically connects the electrodes 121 and 125 of the acoustic wave resonator that are disposed on the substrate 110, and electrodes of other acoustic wave resonators disposed adjacent to each other.

At least a portion of the first metal layer 180 may be in contact with the protective layer 160, and may be bonded to the first electrode 121.

Additionally, in the resonator 120, the first electrode 121 may be formed to have a larger area than the second electrode 125, and a first metal layer 180 may be formed in a peripheral portion of the first electrode 121. Therefore, the first metal layer 180 may be disposed at the periphery of the resonator 120, and accordingly, may be disposed to surround the second electrode 125. However, the one or more examples are not limited thereto.

Next, an acoustic wave resonator package, in accordance with one or more embodiments, will be described.

FIG. 5 is a cross-sectional view schematically illustrating an acoustic wave resonator package, in accordance with one or more embodiments.

Referring to FIG. 5, the acoustic wave resonator package, in accordance with one or more embodiments, may include a cover 60 that protects the resonator 120 of the acoustic wave resonator 100 from an external environment.

The cover 60, in accordance with one or more embodiments, may be formed, as a non-limiting example, of a glass material, and may be bonded to the substrate 110 through a bonding member 80.

The bonding member 80 may be disposed to continuously surround an acoustic wave generator. Accordingly, an inner space P defined by the bonding member 80 and the cover 60 may be formed as an enclosed space.

In an example, the acoustic wave generator is a portion that substantially generates acoustic waves, and may include the resonator 120, the first metal layer 180, and the second metal layer 190. However, the examples are not limited thereto.

As a bonding method of the cover 60, glass frit bonding using glass frit may be used. Glass frit is a piece of glass that is quenched by dissolving a glass raw material at a high temperature, and a paste containing glass frit may be used as the bonding member 80 of the present embodiment.

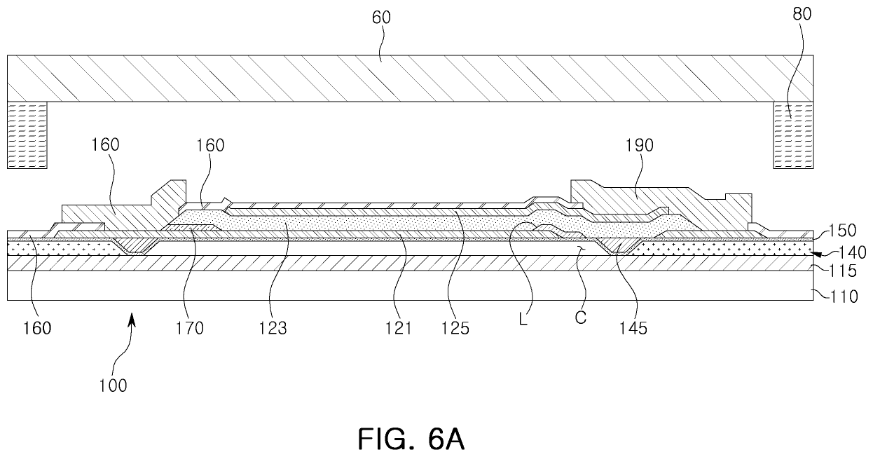

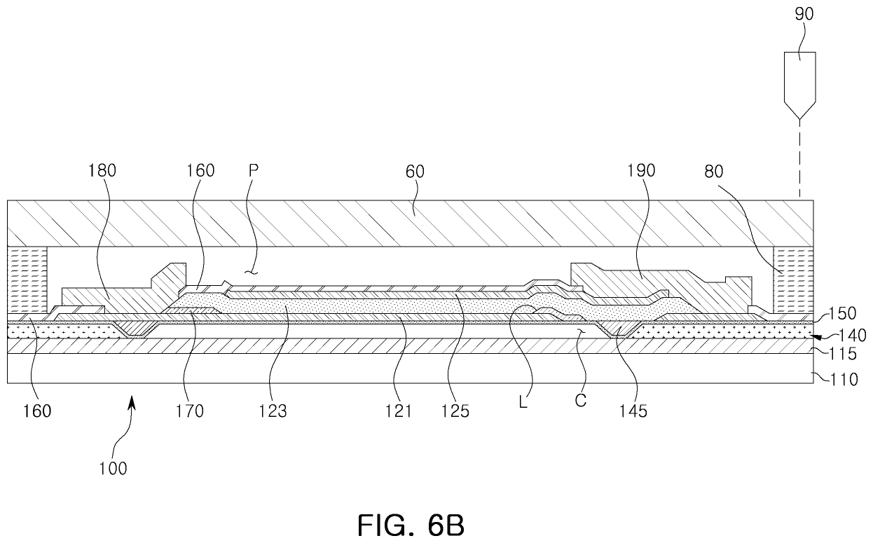

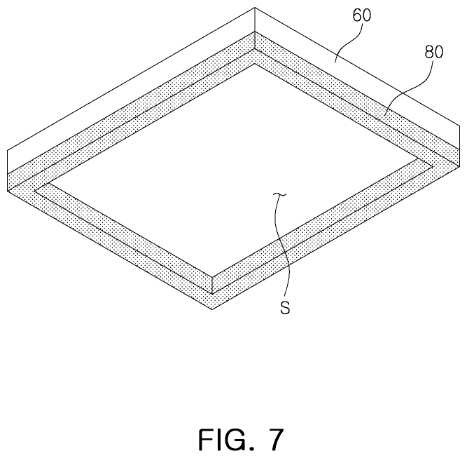

FIGS. 6A to 7 are views illustrating a method of manufacturing the acoustic wave resonator package illustrated in FIG. 5. Here, FIG. 7 is a bottom perspective view of the cover and the bonding member illustrated in FIG. 5.

First, referring to FIG. 6A, in the method of manufacturing the acoustic wave resonator package, in accordance with one or more embodiments, an operation of first applying the bonding member 80 to the cover 60 may be performed.

As described above, a paste containing glass frit may be used as the bonding member 80.

As illustrated in FIG. 7, the bonding member 80 may be disposed along an edge of the cover 60, and may be applied to continuously surround the acoustic wave generator. Additionally, the bonding member 80 may be applied to a position corresponding to the bonding surface of the acoustic wave resonator 100.

One or more examples where the bonding member 80 is applied to the cover 60 is disclosed. However, the one or more examples are not limited thereto, and the bonding member 80 may be applied to the acoustic wave resonator 100, if necessary.

Subsequently, as illustrated in FIG. 6B, an operation of coupling the cover 60 and the acoustic wave resonator 100 may be performed. In such an example, the cover 60 and the acoustic wave resonator 100 may be spaced apart from each other by a predetermined distance by the bonding member 80 without being in contact with each other.

Subsequently, an operation of fusion bonding the cover 60 and the substrate 110 by irradiating a laser to the bonding member 80 through a laser irradiation device 90 may be performed. In the example operation, the laser may be irradiated to the bonding member 80 by passing through the cover 60 formed of glass. Accordingly, the bonding member 80 may be cured to firmly bond the cover 60 and the acoustic wave resonator 100 to each other.

Accordingly, in the one or more examples, the bonding member 80 may include glass frit that is cured through laser absorption, and may include, for example, any one of V₂O₃, TaO₂, B₂O₃, ZnO, B₂O₃, and Bi₂O₃.

In an example of the above-described bonding member 80, high bonding strength may be provided to the cover 60 formed of glass, but the bonding strength with the acoustic wave resonator 100 may be reduced depending on a material of the bonding surface of the acoustic wave resonator 100.

Accordingly, in order to secure bonding reliability between the bonding member 80 and the acoustic wave resonator 100, it is necessary to form the bonding surface of the acoustic wave resonator 100 with a material having high bonding strength with the bonding member 80.

Accordingly, in the acoustic wave resonator 100 of the one or more examples, the bonding surface to be bonded to the bonding member 80 may be formed of a dielectric material.

The dielectric material may include any one of SiO₂, Si₃N₄, TiO₂, Al₂O₃, AlN, ZrO₂, amorphous silicon (a-Si), and poly-silicon (Poly-Si), but is not limited thereto.

As described above, the protective layer 160 of the one or more examples may be formed of any one of the above-described dielectric materials. Accordingly, in the one or more examples, the bonding member 80 may be bonded to the protective layer 160.

However, the one or more examples are not limited thereto, and as described above, since the insertion layer 170, the membrane layer 150, the support layer 140, and the insulating layer 115 may all be formed of the above-described dielectric material, the bonding member 80 of the present disclosure may be bonded to any one of the insertion layer 170, the membrane layer 150, the support layer 140, and the insulating layer 115.

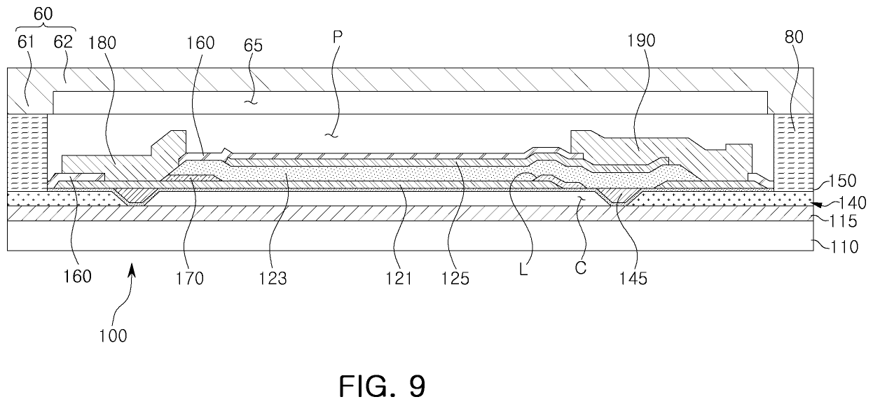

In an example, as illustrated in FIG. 9, the bonding member 80 may be bonded to the support layer 140. In such an example, the bonding member 80 may pass through the membrane layer 150 and the protective layer 160 stacked on the support layer 140, and may be bonded to the support layer 140.

In an example, in an acoustic wave resonator package manufacturing method, in accordance with one or more embodiments, a plurality of acoustic wave resonators 100 may be manufactured on one surface of a wafer, and a cover 60, that covers an entire surface of the wafer, may be bonded to the wafer such that the plurality of acoustic wave resonator packages 10 may be manufactured in batches.

Since the acoustic wave resonator package, in accordance with one or more embodiments, configured as described above may form an enclosed space in which a resonator is disposed by using a glass substrate and glass frit, the acoustic wave resonator package may be is easily manufactured. Additionally, manufacturing costs can be minimized compared to the example of bonding the cover to the acoustic wave resonator by eutectic bonding or metal bonding.

The configuration of the one or more examples is not limited to the above-described embodiment, and various modifications are possible.

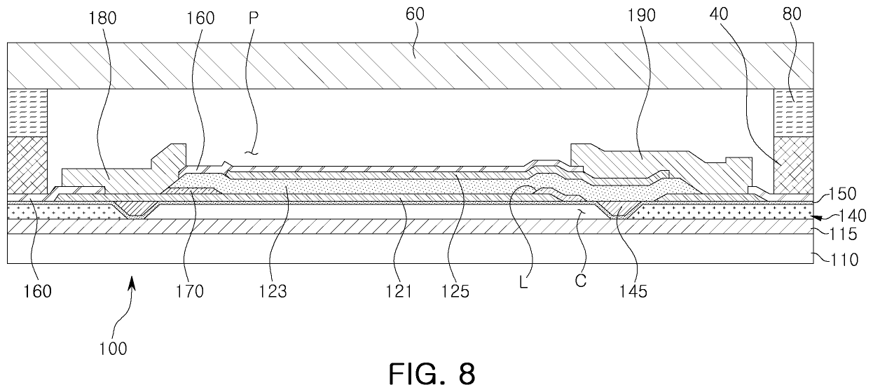

FIG. 8 is a cross-sectional view schematically illustrating an example acoustic wave resonator package, in accordance with one or more embodiments.

Referring to FIG. 8, an acoustic wave resonator package 100, in accordance with one or more embodiments, may include a support portion 40.

The support portion 40 may be disposed between a substrate 110 and a cover 60 to secure a separation distance between the cover 60 and the substrate 110.

When the separation distance between the cover 60 and the resonator 120 is narrow, the acoustic wave generator may be in contact with the cover 60 and may be damaged when the acoustic wave resonator 100 operates. Therefore, a separation distance that may prevent the contact described above between the cover 60 and the resonator 120 should be secured.

Since the bonding member 80 may be applied in a form of a paste, when it is contracted during curing, the bonding member 80 may be reduced to less than the above separation distance. Therefore, in one or more examples, a support portion 40 may be provided to secure the separation distance.

In a non-limiting example, the support portion 40 may be disposed on the acoustic wave resonator 100 to face the bonding member 80. In an example, the support portion 40 may be disposed along a contact surface where the bonding member 80 and the acoustic wave resonator 100 are bonded in the acoustic wave resonator package 10 described above.

Additionally, the bonding member 80 of one or more examples may be bonded to an upper surface of the support portion 40. Accordingly, in one or more examples, the upper surface of the support portion 40 may form the above-described bonding surface.

Since the support portion 40 may be provided to secure the above-described separation distance, an upper end of the support portion 40 may be disposed closer to the cover 60 than an upper end of the acoustic wave generator with reference to FIG. 8.

In order to secure bonding reliability with the bonding member 80, the support portion 40 may be formed of a dielectric material. However, the one or more examples are not limited thereto, and various modifications such as forming the support portion 40 with a metal material and forming a dielectric layer only on the upper surface of the support portion 40 are possible.

The acoustic resonance package 100 of one or more examples configured as described above can stably secure the internal space in which the acoustic wave generator is disposed by using the support portion 40 even when the flat cover 60 is used, thereby ensuring operational reliability.

FIG. 9 is a cross-sectional view schematically illustrating an example acoustic wave resonator package, in accordance with one or more embodiments.

Referring to FIG. 9, in the example acoustic wave resonator package, a groove 65 may be formed in an inner surface of a cover 60.

The groove 65 may be formed to expand an internal space in which an acoustic wave generator is disposed. Accordingly, the groove 65 may be formed to reduce the thickness of the cover 60, and may be formed in a region facing the acoustic wave generator.

The groove 65 may be formed to a depth that may prevent contact between the cover 60 and the acoustic wave generator. Therefore, when the thickness of a bonding member 80 is thick, the depth of the groove 65 may be shallow, and when the thickness of the bonding member 80 is thin, the depth of the groove 65 may be formed to be relatively deep.

In a non-limiting example, the groove 65 may be formed by an etching method, or the like, but is not limited thereto.

In an example, the groove 65 may not be formed in a region in which the bonding member 80 is bonded in the cover 60. Accordingly, the cover 60 of the one or more examples may be formed in a form of a cap having an internal space in which the acoustic wave generator is accommodated.

Accordingly, the cover 60 of the one or more examples may include a side wall 61 and an upper surface portion 62 that connects an upper portion of the side wall 61, and may be bonded to the acoustic wave resonator 120 in a form in which the side wall 61 surrounds the acoustic wave generator.

The acoustic resonance package of one or more examples configured as described above may secure an internal space in which the acoustic wave generator is disposed even if a separate support portion is not provided, thereby reducing manufacturing time and manufacturing cost.

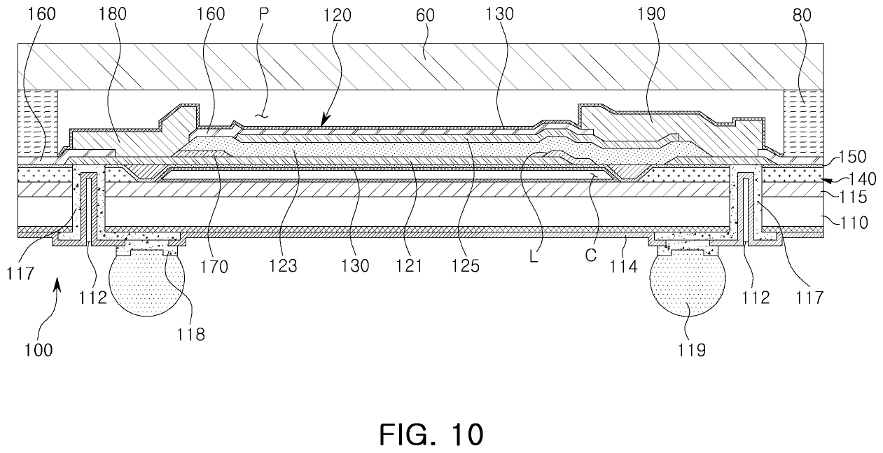

FIG. 10 is a cross-sectional view schematically illustrating an example acoustic wave resonator package, in accordance with one or more embodiments.

Referring to FIG. 10, the example acoustic wave resonator package may be configured similarly to the example acoustic wave resonator package illustrated in FIG. 5, and may further include a hydrophobic layer 130.

The hydrophobic layer 130 may be formed along a surface of an acoustic wave resonator 100. In an example, the hydrophobic layer 130 may be formed on an entire surface of the acoustic wave resonator 100, which may be in contact with air.

Accordingly, in the example acoustic wave resonator package 10, the hydrophobic layer 130 may be disposed along the surface of the acoustic wave generator, and in addition thereto, a hydrophobic layer may also be disposed on an inner wall of a cavity C. However, the configuration of the present disclosure is not limited thereto, and if necessary, the hydrophobic layer 130 may also be partially formed.

When the hydrophobic layer 130 is provided, it is possible to suppress adsorption of particles such as mist and fumes generated in a process of curing a bonding member 80 to the surface of the acoustic wave resonator 100.

These particles may act as a factor to increase a fluctuation amount and standard deviation of a resonant frequency by changing a mass of a resonator 120. However, when the hydrophobic layer 130 is provided as in the present embodiment, water and hydroxyl groups (OH groups) may not be not easily adsorbed to the surface because surface energy of the acoustic wave resonator 100 is low and stable. Therefore, fluctuations in frequency can be minimized, and thus, the performance of the acoustic wave resonator 100 can be uniformly maintained.

The hydrophobic layer 130 may be formed of a self-assembled monolayer (SAM) formation material rather than polymer. When the hydrophobic layer 130 is formed of polymer, the mass by the polymer may affect the resonator 120. However, in the example acoustic wave resonator 100, in accordance with one or more embodiments, since the hydrophobic layer 130 is formed of a self-assembled monolayer, it is possible to minimize fluctuations in the resonant frequency of the acoustic wave resonator 100.

The hydrophobic layer 130 may be formed by performing vapor-deposition on a precursor having hydrophobicity. In such an example, the hydrophobic layer 130 may be deposited as a monolayer having a thickness of 100 Å or less (e.g., several A to several tens of A). The precursor material having hydrophobicity may be formed of a material having a contact angle with water of 90° or more after deposition. In an example, the hydrophobic layer 130 may contain a fluorine (F) component, and may include fluorine (F) and silicon (Si). Specifically, fluorocarbon having a silicon head may be used, but is not limited thereto.

In an example, in order to improve adhesion between the self-assembled monolayer constituting the hydrophobic layer 130 and the protective layer 160, a bonding layer (not shown) may be formed on a surface of the protective layer 160 first, prior to forming the hydrophobic layer 130.

The bonding layer may be formed by performing vapor-deposition on a precursor having a hydrophobicity functional group on the surface of the protective layer 160.

A precursor used for deposition of the bonding layer may be hydrocarbon having a silicon head or siloxane having a silicon head, but is not limited thereto.

Additionally, the substrate 110 of the one or more embodiments may include a via hole 112 that penetrates through the substrate in a thickness direction. Additionally, a connection conductor 117 may be disposed inside each via hole 112.

The connection conductor 117 may be formed on an entire inner surface of the via hole 112 in a form of being coated on the inner surface. However, the present disclosure is not limited thereto, and it is also possible to only form a portion of the inner surface. In addition, it may be formed to fill the entire interior of the via hole 112.

The connection conductor 117 may have one end connected to a connection pad 118 formed on a lower surface of the substrate 110 and the other end electrically connected to the first electrode 121 or the second electrode 125. Accordingly, the connection conductor 117 may be disposed to penetrate the substrate 110 to electrically connect the acoustic wave generator and the connection terminal 119.

In one or more examples, only two via holes 112 and two connection conductors 117 are illustrated and described. However, the examples are not limited thereto, and a larger number of via holes 112 and connection conductors 117 may be provided, as necessary.

At least a portion of the connection conductors 117 may extend to the lower surface of the substrate 110.

A plurality of connection pads 118 may be disposed on the lower surface of the substrate 110. Connection terminals 119 are bonded to the respective connection pads 118.

The connection pad 118 may be formed of a conductive material, and may be disposed to be stacked on the connection conductor 117 disposed on the lower surface of the substrate 110.

A lower protective layer 114 may be formed on the lower surface of the substrate 110. The lower protective layer 114 may be formed of an insulating film such as solder resist, but is not limited thereto.

At least a portion of the connection pad 118 may be exposed externally of the lower protective layer 114, and the connection terminal 119 may be attached to the exposed region.

The connection terminal 119 may be disposed on the lower surface of the substrate 110 and may be used as an element to bond the acoustic wave resonator package and a main board to each other when the acoustic wave resonator package is mounted on the main board.

Therefore, the connection terminal 119 may be formed of a conductive material and may be formed in a form of a solder ball or a solder bump. However, the one or more examples are not limited thereto, and as long as the main board and the acoustic wave resonator 100 can be electrically and physically connected, the connection terminal 119 may be formed in various shapes.

As set forth above, in the acoustic wave resonator according to the present disclosure, since an enclosed space in which an acoustic wave resonator is disposed is formed using a glass substrate and glass frit, the acoustic wave resonator according to the present disclosure may be easily manufactured. Additionally, manufacturing costs may be minimized compared to the example in which a cover is bonded to a substrate by eutectic bonding or metal bonding.

For example, although the above-described embodiments have been described using a bulk-acoustic wave resonator as an example, it is also possible to apply the above-described embodiment to a surface acoustic wave resonator (SAWR).

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic wave resonator package, comprising:
an acoustic wave resonator comprising an acoustic wave generator disposed on a first surface of a substrate;
a cover disposed to face the first surface of the substrate;
a bonding member, disposed between the substrate and the cover, and configured to bond a bonding surface of the acoustic wave resonator and the cover to each other,
wherein the bonding member comprises glass frit, and
wherein the bonding surface of the acoustic wave resonator is formed of a dielectric material.

2. The acoustic wave resonator package of claim 1, wherein the cover is formed of a glass material.

3. The acoustic wave resonator package of claim 1, wherein the bonding member is disposed along an edge of the cover, and is disposed to continuously surround the acoustic wave generator.

4. The acoustic wave resonator package of claim 1, wherein the bonding member comprises any one of V₂O₃, TaO₂, B₂O₃, ZnO, B₂O₃, and Bi₂O₃.

5. The acoustic wave resonator package of claim 1, wherein the bonding surface of the acoustic wave resonator is formed of any one of SiO₂, Si₃N₄, TiO₂, Al₂O₃, AlN, ZrO₂, amorphous silicon, and poly-silicon.

6. The acoustic wave resonator package of claim 1, wherein the acoustic wave generator comprises a resonator having a first electrode, a piezoelectric layer, and a second electrode sequentially stacked on the substrate.

7. The acoustic wave resonator package of claim 6, wherein the acoustic wave resonator further comprises a protective layer disposed along a surface of the acoustic wave generator, and
wherein the bonding member is bonded to the protective layer.

8. The acoustic wave resonator package of claim 7, wherein the protective layer is formed of any one of SiO₂, Si₃N₄, TiO₂, Al₂O₃, AlN, ZrO₂, amorphous silicon (a-Si), and poly-silicon (Poly Si).

9. The acoustic wave resonator package of claim 6, wherein the acoustic wave resonator further comprises a support layer, disposed between the resonator and the substrate, and configured to separate the resonator and the substrate by a predetermined distance, and
wherein the bonding member is bonded to the support layer.

10. The acoustic wave resonator package of claim 9, wherein the support layer is formed of a poly-silicon (Poly Si) material.

11. The acoustic wave resonator package of claim 1, further comprising a support portion, disposed on the acoustic wave resonator, and configured to face the bonding member,
wherein an upper surface of the support portion is configured to form a bonding surface of the acoustic wave resonator.

12. The acoustic wave resonator package of claim 11, wherein an upper end of the support portion is disposed to be closer to the cover than an upper end of the acoustic wave generator.

13. The acoustic wave resonator package of claim 1, wherein the cover is configured to have a groove in a region that faces the acoustic wave generator.

14. The acoustic wave resonator package of claim 1, wherein the acoustic wave resonator further comprises a hydrophobic layer disposed along a surface of the acoustic wave generator.

15. The acoustic wave resonator package of claim 1, further comprising:
a connection terminal disposed on a second surface of the substrate; and
a connection conductor disposed to pass through the substrate and electrically connect the acoustic wave generator to the connection terminal.

16. An acoustic wave resonator package, comprising:
an acoustic wave resonator comprising an acoustic wave generator disposed on a first surface of a substrate;
a cover formed of a glass material, and disposed to face the first surface of the substrate; and
a bonding member disposed between the substrate and the cover, and configured to bond the acoustic wave resonator and the cover to each other,
wherein the bonding member comprises glass frit, and
wherein the cover is configured to have a groove in a region that faces the acoustic wave generator.

17. An acoustic wave resonator package, comprising:
a resonator disposed on a first surface of a substrate;
a cover disposed over the resonator;
an insulating layer provided on an upper surface of the substrate; and
a bonding member configured to bond the cover to the insulating layer;
wherein the cover is formed of a glass material, and
wherein the bonding material comprises glass frit.

18. The acoustic wave resonator package of claim 17, wherein the bonding member is formed of one of V₂O₃, TaO₂, B₂O₃, ZnO, B₂O₃, and Bi₂O₃.
